(19) United States
(12) Patent Application Publication
(10) Pub. No.: US 2009/0218649 A1
(43) Pub. Date: Sep. 3, 2009

(54) Highly efficient silicon detector with wide spectral range

(75) Inventors: Mariano Aceves Mijares, Puebla (MX); Carlos Dominguez Horna, Puebla (MX); Luis Berriel Valdos, Puebla (MX); Dainet Berman Mendoza, Puebla (MX)

Correspondence Address: Carmen Pili Ekstrom, 727 Sunshine Dr., Los Altos, CA, 94024, US

(73) Assignee: Instituto Nacionaf De Astrofisica Optica Y Electronica

(21) Appl. No.: 12/322,429

(22) Filed: Jan. 31, 2009

(30) Foreign Application Priority Data
Nov. 21, 2007 (MX) MX/A/2007/015027

(51) Int. Cl. H01L 31/0216; H01L 31/18; H01L 21/00

(52) U.S. Cl. 257/436; 438/69; 257/E31.119; 257/E21.211

(57) ABSTRACT

High efficiency silicon radiation detector from ultraviolet to near infrared region, including a structure with a wide spectral range that work at the ultraviolet region, said structure, comprises a silicon photodetector with an excess of silicon 3-10%, and annealing temperature at 1100° C., increasing the wave length range from 200 to 1100 nm.

### BACKGROUND OF INVENTION

1. Field of Invention

The ultraviolet radiation sensor of high efficiency, have an off stoichiometric silicon oxide photoluminescence layer (SiOₓ) on a silicon photodetector. The SiOₓ is used as a high efficient wavelength “shifter”. The technology used is compatible with that of silicon, and thus the manufacturing process is economical.

2. State of the Art

There are different kinds of Ultraviolet (UV) radiation sensor:

CCD coated with organic phosphorus with a detection range from 254 nm to 365 nm. This kind of sensor uses a coating layer of inorganic phosphorus made of three materials: a matrix of acrylic, phosphorus and organic solvent. The coating is deposited within slots of silicon. This CCD present maximum quantum efficiency of 12% at 265 nm. It main disadvantage is that its manufacturing process is not compatible with that of the MOS devices because the acrylic cannot tolerate high temperatures. Its main application is in the manufacturing industry.

Integrated photodiodes in a bipolar optoelectronic circuit for detecting ultraviolet radiation are mainly used for detection of flame in the industry, and its spectral range goes from 200 nm to 400 nm. Shallow P+ and N− implanted regions are used in order to produce the depletion region near the surface where UV light is absorbed and carriers are generated. It has a very small photocurrent ranging from 1 pA to 1 nA which makes it very inefficient.

Shottky Ag-Gap photodiodes are manufactured by dispersion of metals (Ag, Au, Pt) on layers of n-Gap grown by liquid phase epitaxial (LPE) or vapor phase epitaxial (VPE). The metal is deposited in a vacuum and by magnetron scattering. These devices have responsivity of 0.034 A/W at 420 nm. As can be seen these sensors present improved efficiency in the blue region of the visible spectrum, but this is not the case in the ultraviolet region.

CMOS photodiodes of P+ regions with a finger structure on an N substrate with improved responsivity. In these devices the band gap extends over the entire epitaxial layer. In addition, they use an antireflection coating. This device has a responsivity of 0.23 A/W at 400 nm that is the higher part of the ultraviolet region almost on the blue region of the electromagnetic spectrum, but they continue having low efficiency in the ultraviolet range.

In general terms, currently the UV sensors have many problems for example, low responsivity, or complicated structures, or they are not compatible with the manufacturing technology of silicon electronic devices.

The use of silicon for the manufacture of reliable low cost integrated circuits which perform optoelectronic functions such as detection of high energy photons, and emission of light in the visible region of the electromagnetic spectrum, have been seeking. However, silicon is characterized by an indirect band, so that it is inappropriate to perform optical function such as emission of radiation. Therefore studies are carried out on a wide range of optoelectronic materials compatibles with silicon in order to achieve those functions.

One of these materials is the Silicon Rich oxide (SRO) which appears experimentally at the end of the seventies. This material is obtained by various methods such as: Silicon implantation into thermal oxides (SITO) and chemical vapor deposition (CVD) in all its forms. In particular, we will use the so-called of stoichiometric silicon oxide that is a variation of SRO.

The SRO is a silicon oxide (SiO₂) enriched with silicon (SiOₓ, 0<x<2)). Using the CVD technique, films of SRO can be deposited with a good uniformity, excellent topographic coverage, and low density of defects and also this technology allows creating materials controlling easily its stoichiometry with high precision on broad surfaces. In the CVD process, the excess of silicon on the SRO film is controlled through the relationship of flow of the reactive gases used during the deposit of the film (Ro). For Ro values between 5 and 30, there are excesses of silicon on the SRO between 12.73% and 4.24%. After the deposit of SRO, an annealing is applied to the film at high temperatures to redirect the crystal structure. In stoichiometric silicon dioxide, the oxygen and silicon is 66.7% and 33.3% respectively. Any silicon amount is excess of 33.3% is considered silicon excess. Many studies have been done to determine the origin of the luminescence in the SRO and thus control the ranges of emission. Quantum confinement effects and SiO₂ defects have been proposed as the principal mechanism of the emission, because the properties of the material can vary notably when the silicon crystal size is reduced to particles in the scale of nanometers. Basically the physical and chemical properties of the material are determined by the interactions that exist between the electrons and between the ions and the electrons. By reducing the space where the electrons can move, new effects appear due the spatial confinement of the particles.

The excess of silicon and the form in which it is obtained produce changes in the physical, electrical and optical properties of the SRO. The behavior of the silicon atoms forming the nanocrystals is important. This produces that the diverse ways to obtain SRO generate different responses in the emission. Specifically here we refer to the obtaining method known as low pressure chemical vapor deposition (LPCVD), SiOₓ films that emit in the visible spectrum with high intensity are obtained by this method. Different methods are known for the detection of ultraviolet radiation, for example U.S. Pat. No. 5,093,576 describes a detector of ultraviolet radiation of high sensibility that detects using photodiodes done in silicon carbides, and the substrate is formed by two or more layers of silicon carbide. The sensor provide a current density of less than 1×10⁻⁹ amp/cm². U.S. Pat. No. 5,682,037 describes a thin film detector of ultraviolet radiation with high spectrum of selectivity and a structure formed by the overlapping of thin semiconductor films—as hydrogenated amorphous silicon and its alloys with carbon between two electrodes. The detector can be manufactured on substrates of glass, plastic, metals and ceramic. The European patent EP 0726605 A2 describes a thin film detector of ultraviolet radiation, with the option of high spectral selectivity, which consists of a structure located between two electrodes formed by the overlapping of semiconductor thin films as hydrogenated amorphous silicon and its alloys with carbon.

The previous inventions used a hydrogenated amorphous silicon film with the addition of carbon, while the substrate of the present invention uses a film of silicon rich oxide.

Also, the devices mentioned use as substrate glass, plastic, metal or ceramic, which cannot be subjected to high temperatures, or for other reasons are not compatible with the CMOS to manufacture of integrated circuits.

In the present invention, the device uses a crystalline silicon wafer as substrate, which can be subjected to high temperatures and the manufacturing process is compatible with CMOS technology for the manufacture of integrated circuits.

Therefore, the device uses technology compatible with the silicon processing technology (which is well established and economic), and consequently the devices is very economic.

### DESCRIPTION OF THE INVENTION

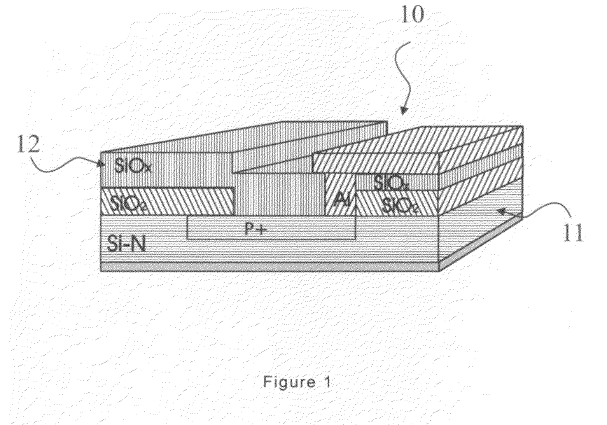

Below, the invention is described as follow from the drawings of the FIGS. 1 to 11.

FIG. 1 Corresponds to the isometric view of the ultraviolet radiation detector structure.

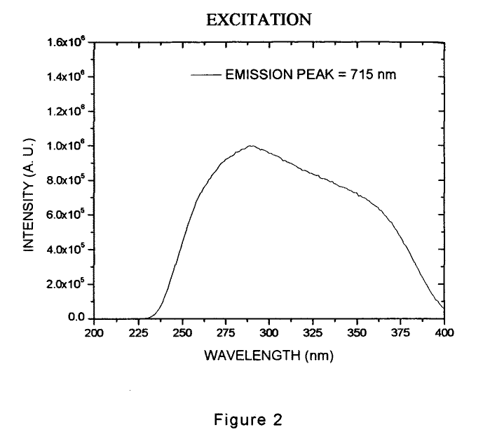

FIG. 2. Corresponds to the excitation curve to obtain photoluminescence in SRO obtained by LPCVD.

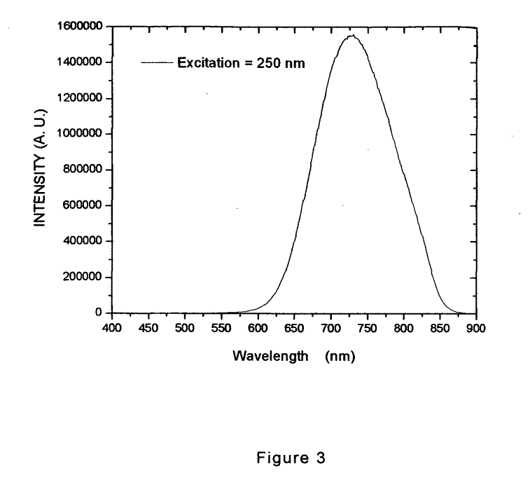

FIG. 3. Corresponds to a graphic of emitted photoluminescence in samples of SiOₓ, obtained by LPCVD and alloyed at 1100° C.

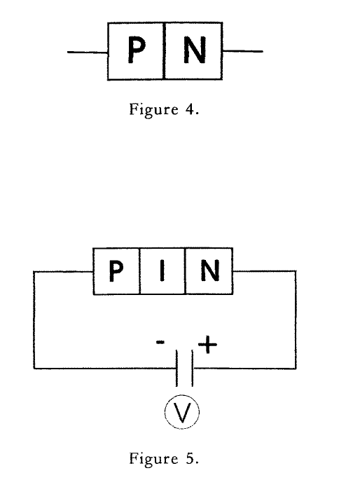

FIG. 4. Corresponds to a P-N diode electric diagram.

FIG. 5 Corresponds to a PIN diode electric diagram inversely polarized.

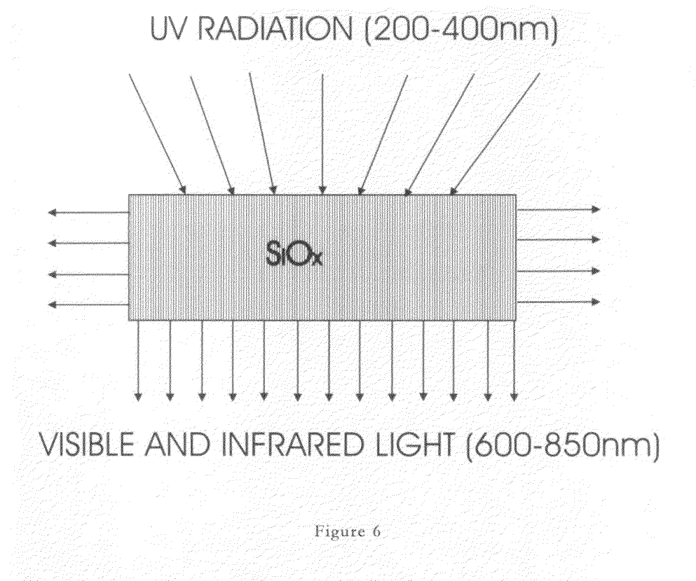

FIG. 6. Corresponds to a SRO excitation and emission curves. This picture shows a shift of the light emitted compared with light applied.

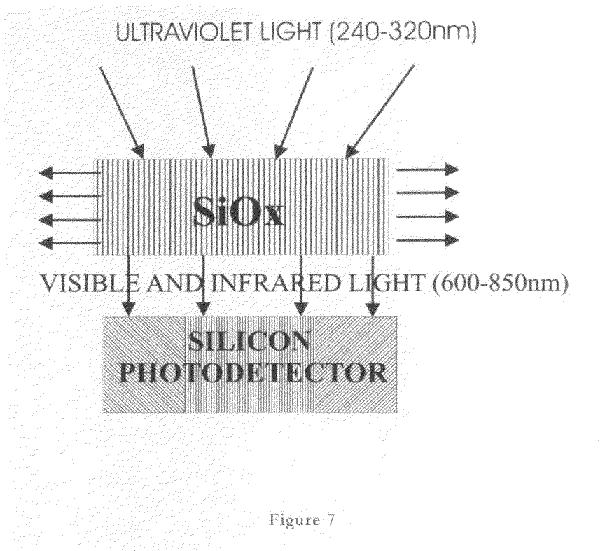

FIG. 7. Corresponds to the whole silicon sensor diagram that can detect from 200 to 1100 nm.

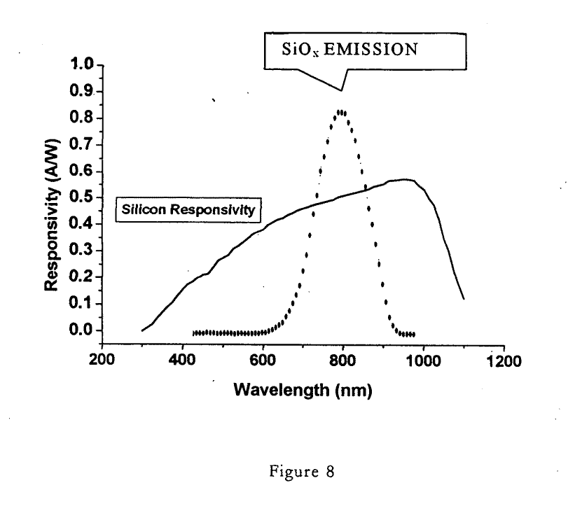

FIG. 8. Corresponds to a conventional PIN photodetector efficiency compared, to the SiOₓ emission, obtained by LPCVD and annealed at 1100° C. with excess silicon in the range of 3 to 10%.

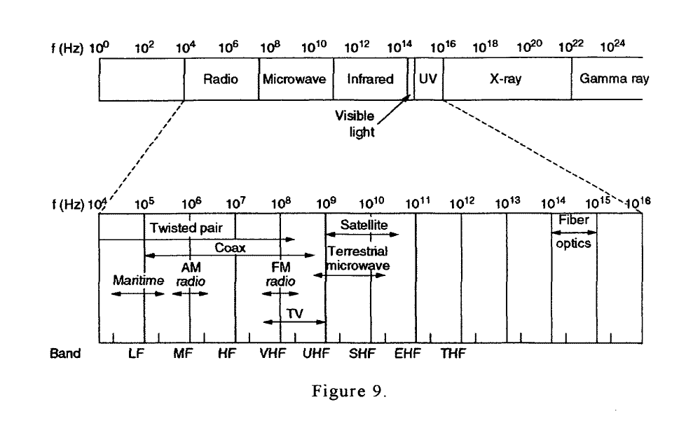

FIG. 9 Corresponds to the electromagnetic spectrum diagram.

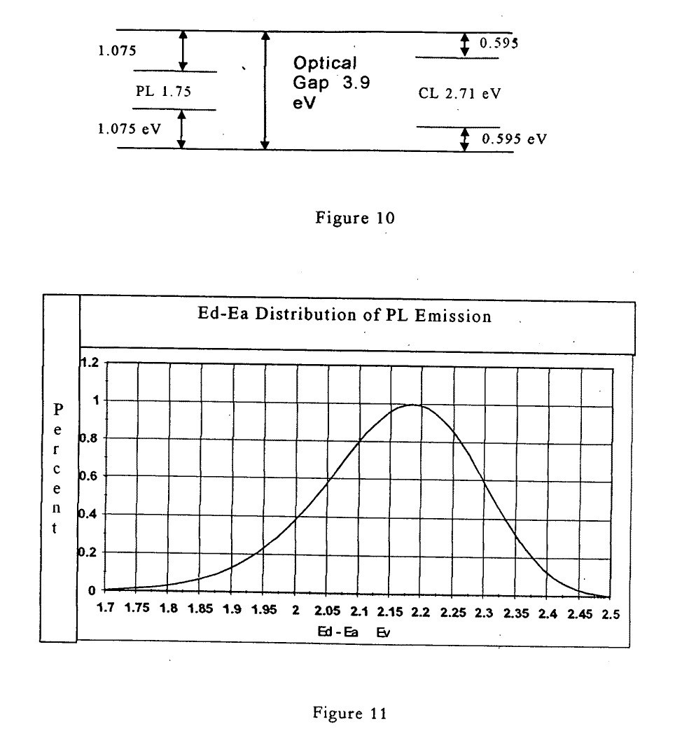

FIG. 10 Corresponds to a simplified diagram of the new emission model of SiOₓ obtained by LPCVD. The new model supposes the electron decay between acceptor and donors pairs (ADP), equivalent to the (ADP) in crystalline semiconductors. This model is one the result of the research done to obtain the sensor.

FIG. 11 Corresponds to the ADP energy distribution of SiOₓ.Ed and Ea are the donor and acceptor energy pair.

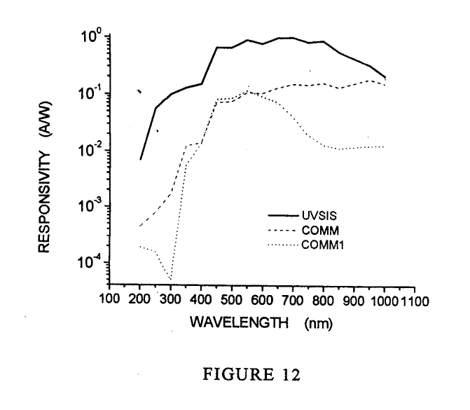

FIG. 12 Corresponds to a comparison between the average responsivity of our UVSIS sensor and two silicon commercial diodes crystalline silicon (54036 and 53375).

It has been observed that when applying thermal annealing treatments at 1100° C. for periods from 30 to 360 minutes to SiOₓ films with excesses silicon between 3% and 10% and thickness between 100 and 1000 nm obtained by LPCVD, the photoluminescence emission increases, and can be used to detect the radiation efficiently in the range of 200 to 400 nm.

When the SiOₓ undergo a thermal treatment at 1100° C. with the excesses of silicon mentioned tends to form oxygen compounds and silicon defects, which can trap or donate an electron. These tramps are impurities or acceptor-donor pairs (ADP) in semiconductors. The electronic decay between ADP produces luminescence in the visible electromagnetic spectrum. In this patent, we combine the high emission of SiOₓ with a silicon detector. In such a way, we extend the ability of the silicon sensor to detect in the UV region to the near infrared (200 to 1100 nm).

On the other hand, excess of silicon greater than those specified herein produces that the silicon excess in the SRO agglomerates and form silicon nanocrystals (SinC) mostly. The SinC keeps the characteristic of an indirect band semiconductor. Also, the formation of SinC produces a very low density of ADP. These two effects combined produce that the SRO emission in the visible spectrum to be very slow. At the other extreme, excesses of silicon less than 3% also emit very low efficiency due to the very low density of defects formed during heat treatment.

With regard to the method of deposition, we have also found that the low pressure chemical vapor deposit (LPCVD) unlike other methods is the most efficient way to produce the decay of ADP. For example, the plasma enhanced chemical vapor deposit (PECVD) method produces nitrogen during the process. Apparently the nitrogen reduces the probability of the formation of ADP, which reduces the emission.

Experimental studies of photoluminescence to determine the technological parameters in order to obtain the maximum emission were done, and then the material obtained can be applied to integrate the sensor using Si technology. It was found that:

Deposit method: Low pressure chemical vapor deposition (LPCVD).

Temperature of annealing: 1100° C.
Time of annealing: 30 to 360 minutes.
Silicon excess: 3 to 10%.

In FIG. 2, it is observed that the radiation applied to the sample of SiOₓ, is in the ultraviolet range (200 to 400 nm) of the electromagnetic spectrum. The FIG. 3 shows the emitted signal by SiOₓ, which shifts the wavelength to the red (650 to 750 nm).

P-N union: is formed in a semiconductor material with different impurities or doping elements in the P and N regions. Then, it is also known as homo-union device (see FIG. 4).

P-N union diode: is a minority carrier device, since the current is controlled by the process of diffusion of minority carrier when the region P and N come in intimate contact. The holes attempt to diffuse from the P region with a high concentration to the N region with a low concentration. Then, the holes leave a negative layer of charged acceptors. Similarly, electrons try to diffuse from the region N into the P region, again leaving a positive layer of charged donors. Therefore, a potential barrier is formed that prevents more carriers continue penetrating each region. This barrier which is called the region of space charge, built an electric field that oppose to the diffusion flow stopping the carriers movement and keeping the equilibrium.

PIN photodetector: The PIN diode is the photodetector most frequently used to detect high energy particles of nuclear radiation, because the depletion width of the diode (region of space charge) can be controlled by the applied voltage at reverse polarization, achieving a high photoresponse in this range.

The photodetector efficiency is considerably improved when the region of space charge expands enough to absorb most of the incident radiation.

A PIN diode is manufactured on an intrinsic semiconductor, with a pair of highly doped region (P region and N region) and an intrinsic region between them. The intrinsic region provides a depletion region large enough that allows the absorption of most of incident radiation (see FIG. 5.).

### Description of the UV Radiation Detector Device

According to FIG. 1, the UV ultraviolet radiation detector device 10 (sensor) is a device comprising of a silicon photodetector 11 in the visible range of the electromagnetic spectrum on which is deposited by LPCVD a film of SiOₓ 12 and then exposed to a heat treatment.

From the various photonic properties of SRO, they regards to the invention only in terms of a wavelength shifter. That is, it is applied excitation energy between 200 to 400 nm, and the material present photoluminescence in the visible-infrared region (600 to 800 nm), as shown in the FIG. 6.

In FIG. 7, it is shown the scheme of the proposed system to detect ultraviolet radiation, the idea is to sense the ultraviolet radiation with the SiOₓ obtained by the LPCVD and annealed at 1100° C., and it should emit (Photoluminescence) in the visible-infrared region (600 to 850 nm). This emission is detected by a silicon photodetector, which can convert light into electrical current proportional to the light shining into it. In this form the device extends the response of Si from 200 to 1100 nm.

FIG. 8 shows the comparison between the responsivity of a commercial PIN photodetector of silicon and the SiOₓ emission. It is noted that there is an interesting correlation between both graphic around 700 and 800 nm, obtaining a greater responsivity of 0.5 A/W.

FIG. 9 describes an electromagnetic spectrum diagram, in which the UV and infrared region are separated by the visible region. Furthermore, the energy of the UV emission is higher than the infrared emission.

Our sensor operates in the UV and infrared region increasing the wavelength range from 200 to 1100 nm, expanding the responsivity of the commercial silicon detector.

FIG. 10 illustrates a band theory diagram that idealizes the SiOₓ as semiconductor with ADP, the model is one of the results from the research done on this material. This idealization match to the maximum emission obtained in the photo and cathode luminescence. Indicating that photoluminescence in a semiconductor is usually the result of a recombination of an electron and a hole. The energy of the emitted photon is that of the electron transition when it decays between the donor and acceptor pair. In order to have photon emission the transition has to be radiative, only direct band materials fulfill this requirement.

FIG. 11 shows the probable distribution of the centers.

The indirect band materials are non radiative because the energy is transformed in crystal oscillations (phonons) instead of emissive energy (photons).

To illustrate the high responsivity of our device in the whole range, FIG. 12 illustrate the comparison between our sensor and two commercial silicon sensors.

### Applications

The storage information market is growing rapidly. At the present the compact discs (CD) have a large storage capacity of 650 to 700 MB, it is expected that future digital video discs (DVD) will storage a capacity of 30 GB, such device will require optical systems with a spectral range of approximately 400 nm (UV/blue) having high sensitivity and responsivity.

Currently, the scientific researchers develop CCD and digital image camera for applications in the ultraviolet region, but it is necessary to improve its poor responsivity in this region of the electromagnetic spectrum.

The UV photodetectors have important applications in biological systems such DNA, recognition of molecules, proteins and others biological phenomena that require fluorescent or luminescent test.

After describing the invention, it is considered as a novelty and therefore it is claimed the contained in the following:

We claim:

1. A high efficiency silicon radiation detector having a spectral range of from ultraviolet to near infrared, the detector comprising: a) a silicon photodetector in the visible range; b) a film of silicon rich oxide enriched with silicon (SiOₓ 0<x<2) on top of the photodetector, deposited by low pressure chemical vapor deposition (LPCVD), having an excess of silicon of between 3 and 10%, a thickness of between 100 and 1000 nm, at an annealing temperature of about 1100° C. for 30 to 360 minutes.

2. The silicon radiation detector of claim 1 having a spectral range of 200 to 1100 nm.

3. The silicon radiation detector of claim 1, wherein the SiOₓ film is a wavelength shifter that works when a wavelength between 200 and 400 nm excites it and the SiOₓ responds with photoluminescence in the visible-infrared region from 600 to 800 nm.

4. The silicon radiation detector of claim 1, wherein the SiOₓ film emits a luminescent signal in the visible-infrared range when a radiation of 200 to 400 nm is applied to the SiOₓ film, and the SiOₓ film sends the luminescent signal to the silicon photodetector which converts the received light into electrical current, the current being directly proportional to the light variation received.

5. The silicon radiation detector of claim 4, wherein the luminescent signal has a wavelength of from 600 to 850 nm.

6. The silicon radiation detector of claim 1, wherein a radiation of between 400 to 1100 nm passes through the SiOₓ film to the silicon photodetector, which efficiently responds to light of 400 to 1100 nm

7. The silicon radiation detector of claim 1, further comprising a substrate made of crystalline silicon wafer which can be subjected to high temperature.

8. The silicon radiation detector of claim 1, wherein in SiOₓ (0<x<2), oxygen is present in an amount of 33.3% and silicon is present in an amount of 66.7%.

9. The silicon radiation detector of claim 8 wherein an amount in excess of 33.3% is a silicon excess, the amount of excess silicon at least 3-10%.

10. A method of preparing a silicon radiation detector comprising the steps of:
a) providing a silicon photodetector in the visible range;
b) depositing a film of silicon rich oxide enriched with silicon (SiOₓ 0<x<2) on top of the photodetector by low pressure chemical vapor deposition (LPCVD);
c) depositing an excess of silicon of between 3 and 10%, at a thickness of between 100 and 1000 nm; and
d) annealing at a temperature of about 1100° C. for 30 to 360 minutes.

11. The method of claim 10 wherein the detector has a spectral range of 200 to 1100 nm.

12. The method of claim 10 wherein in SiOₓ (0<x<2), oxygen is present in an amount of 33.3% and silicon is present in an amount of 66.7%.

13. The method of claim 12 wherein an amount in excess of 33.3% is a silicon excess.

14. The method of claim 10 further comprising applying radiation of 200 to 400 nm to the SiOₓ film and the SiOₓ film sends the luminescent signal to the silicon photodetector which converts the received light into electrical current, the current being directly proportional to the light variation received.

15. The method of claim 14, wherein the SiOₓ film emits a luminescent signal in the visible-infrared range.

16. The method of claim 14, wherein the luminescent signal has a wavelength of from 600 to 850 nm.

17. The method of claim 10, further comprising passing a radiation of between 400 to 1100 nm through the SiOₓ film to the silicon photodetector, which efficiently responds to light of 400 to 1100 nm.

18. The method of claim 10, further comprising employing a substrate made of crystalline silicon wafer which can be subjected to high temperature.

19. The method of claim 10, further comprising exciting the SiOₓ film at a wavelength between 200 and 400 nm and the SiOₓ responds with photoluminescence in the visible-infrared region from 600 to 800 nm.

20. The method of claim 10 wherein the process is compatible with CMOS technology for the manufacture of integrated circuits.
